(19) United States
(12) Patent Application Publication
(10) Pub. No.: US 2024/0268155 A1
(43) Pub. Date: Aug. 8, 2024

(54) DISPLAY DEVICE

(71) Applicant: SAMSUNG DISPLAY CO., LTD., YONGIN-SI (KR)

(72) Inventors: Soo Min BAEK, YONGIN-SI (KR); Cheon Myeong LEE, YONGIN-SI (KR); Bek Hyun LIM, YONGIN-SI (KR); Ju Hwa HA, YONGIN-SI (KR); Sang Ho KIM, YONGIN-SI (KR); Ju Youn SON, YONGIN-SI (KR); Ji Won LEE, YONGIN-SI (KR)

(21) Appl. No.: 18/430,745

(22) Filed: Feb. 2, 2024

(30) Foreign Application Priority Data
Feb. 7, 2023 (KR) 10-2023-0016061

(51) Int. Cl. H10K 59/122; H10K 59/80

(52) U.S. Cl. CPC H10K 59/122; H10K 59/873; H10K 59/879; H10K 59/8792

(57) ABSTRACT

A display device includes a substrate, a bank disposed on the substrate and having a multi-layered structure having an opening, a light emitting element disposed in the opening and including a pixel electrode, a light emitting layer, and a common electrode, a thin film encapsulating layer disposed on the light emitting element and the bank, a micro lens disposed on the thin film encapsulating layer and overlapping the light emitting element, and a light control layer disposed on the thin film encapsulating layer and surrounding the micro lens. A refractive index of the micro lens is greater than a refractive index of the light control layer.

The pixel electrode is disposed in the opening and extends along an inner surface of the bank, and the light emitting layer extends along the inner surface of the bank on the pixel electrode.

### CROSS-REFERENCE TO RELATED APPLICATION

This application claims priority under 35 U.S.C. § 119 to Korean Patent Application No. 10-2023-0016061, filed on Feb. 7, 2023 in the Korean Intellectual Property Office, the disclosure of which is incorporated by reference herein in its entirety.

### TECHNICAL FIELD

Embodiments of the present disclosure relate to a display device.

### DISCUSSION OF RELATED ART

In an organic light emitting diode (OLED) display device, an image may be displayed using an organic light emitting element that generates light by recombination of electrons and holes. Such a display device may have a fast response speed, a high luminance, a desirable viewing angle, and may be driven with low power consumption.

A head-mounted display device may be mounted on a user's head and may have a shape such as, for example, glasses or a helmet. A head mounted display device allows a user to recognize an image by displaying an image in front of the user's eyes.

### SUMMARY

Aspects and features of embodiments of the present disclosure provide a display device having high light extraction efficiency.

In addition, aspects and features of embodiments of the present disclosure provide a display device and a head-mounted display device capable of improving the screen door effect.

According to an embodiment, a display device includes a substrate, a bank disposed on the substrate and having a multi-layered structure having an opening, a light emitting element disposed in the opening and including a pixel electrode, a light emitting layer, and a common electrode, a thin film encapsulating layer disposed on the light emitting element and the bank, a micro lens disposed on the thin film encapsulating layer and overlapping the light emitting element, and a light control layer disposed on the thin film encapsulating layer and surrounding the micro lens. A refractive index of the micro lens is greater than a refractive index of the light control layer. The pixel electrode is disposed in the opening and extends along an inner surface of the bank, and the light emitting layer extends along the inner surface of the bank on the pixel electrode.

In an embodiment, the pixel electrode includes a first pixel electrode and a second pixel electrode disposed on the first pixel electrode. The bank includes a first bank including a first inner surface covering an end of the first pixel electrode and defining a first opening and a second bank disposed on the first bank and including a second inner surface defining a second opening corresponding to the first opening. A width of the second opening is wider than a width of the first opening.

In an embodiment, a second interval angle between an upper surface of the substrate and the second inner surface of the second bank is greater than a first interval angle between the upper surface of the substrate and the first inner surface of the first bank.

In an embodiment, the second pixel electrode includes a first electrode area disposed inside the first opening, a second electrode area extending from the first electrode area along the first inner surface of the first bank, and a third electrode area extending from the second electrode area and covering at least a portion of an upper portion of the first bank exposed by the second opening.

In an embodiment, the light emitting layer includes a first light emitting layer area disposed inside the first opening on the first electrode area, a second light emitting layer area extending along the first inner surface of the first bank on the second electrode area, and a third light emitting layer area extending from the second light emitting layer area and disposed on the third electrode area.

In an embodiment, the third light emitting layer area covers the third electrode area.

In an embodiment, the second pixel electrode includes a first electrode area disposed inside the first opening, a second electrode area extending from the first electrode area along the first inner surface of the first bank, a third electrode area extended from the second electrode area and covering an upper portion of the first bank exposed by the second opening, and a fourth electrode area extending from the third electrode area along the second inner surface of the second bank.

In an embodiment, the light emitting layer includes a first light emitting layer area disposed inside the first opening on the first electrode area, a second light emitting layer area extending from the second electrode area along the first inner surface of the first bank, a third light emitting layer area extending from the second light emitting layer area and disposed on the third electrode area, a fourth light emitting layer area extending along the second inner surface of the second bank from the third light emitting layer area on the fourth electrode area, and a fifth light emitting layer area extending from the fourth light emitting layer area and covering a portion of an upper portion of the second bank.

In an embodiment, the fifth light emitting layer area has a thickness that gradually decreases toward an edge.

In an embodiment, the fifth light emitting layer area partially overlaps the light control layer.

In an embodiment, the display device further includes a capping layer disposed on the bank. The micro lens and the light control layer are disposed on the capping layer. The refractive index of the micro lens is less than or equal to a refractive index of the capping layer.

In an embodiment, the refractive index of the micro lens differs from the refractive index of the light control layer by about 0.1 or more and about 0.2 or less.

In an embodiment, a diameter of the micro lens is larger than a diameter of the second opening.

In an embodiment, the micro lens has a curvature of about 0.12 or more and about 0.2 or less.

In an embodiment, the light control layer has an inclination angle on a surface in contact with the micro lens, and the inclination angle is greater than the second internal angle.

In an embodiment, at least one of the first bank and the second bank includes an opaque material that blocks light.

In an embodiment, at least one of the first bank and the second bank is formed of a transparent organic material.

In an embodiment, the display device further includes a light blocking pattern disposed under the light control layer and covered by the light control layer.

According to an embodiment, a display device includes a substrate, a bank disposed on the substrate and having a multi-layered structure having an opening, a light emitting element disposed in the opening and including a pixel electrode, a light emitting layer, and a common electrode, a thin film encapsulating layer disposed on the light emitting element and the bank, a capping layer disposed on the thin film encapsulating layer, a micro lens disposed on the capping layer and overlapping the light emitting element, and a light control layer disposed on the capping layer and surrounding the micro lens. A refractive index of the micro lens is greater than a refractive index of the light control layer and less than or equal to a refractive index of the capping layer, and the light emitting layer extends along an inner surface of the bank on the pixel electrode.

In an embodiment, a refractive index of the micro lens differs from a refractive index of the light control layer by about 0.1 or more and about 0.2 or less.

In an embodiment, the pixel electrode includes a first pixel electrode and a second pixel electrode disposed on the first pixel electrode, the bank includes a first bank including a first inner surface covering an end of the first pixel electrode and defining a first opening and a second bank disposed on the first bank and including a second inner surface defining a second opening corresponding to the first opening, and a width of the second opening is wider than a width of the first opening.

In an embodiment, a second internal angle between an upper surface of the substrate and the second inner surface of the second bank is greater than a first internal angle between the upper surface of the substrate and the first inner surface of the first bank.

In an embodiment, the light emitting layer partially overlaps the light control layer.

According to embodiments of the present disclosure, the external light emitting efficiency may be improved by expanding the light emitting area and totally reflecting the light emitted.

In addition, the screen door effect of the display device may be improved.

### BRIEF DESCRIPTION OF THE DRAWINGS

The above and other features of the present disclosure will become more apparent by describing in detail embodiments thereof with reference to the accompanying drawings.

FIG. 1 is a perspective view illustrating a display device according to an embodiment of the present disclosure.

FIG. 2 is a cross-sectional view of the display device of FIG. 1 taken along line Xa-Xa′ of FIG. 1.

FIG. 3 is an equivalent circuit diagram of any one pixel included in a display device according to an embodiment of the present disclosure.

FIG. 4 is a detailed cross-sectional view of a part of the display device of FIG. 1.

FIG. 5 is a cross-sectional view of a micro lens array layer.

FIG. 6 is a cross-sectional view illustrating one pixel of a display panel according to an embodiment of the present disclosure.

FIG. 7 is an enlarged view of area A of FIG. 6.

FIG. 8 is a cross-sectional view illustrating one pixel of a display panel according to an embodiment of the present disclosure.

FIG. 9 is a cross-sectional view illustrating one pixel of a display panel according to an embodiment of the present disclosure.

FIG. 10 is a cross-sectional view illustrating one pixel of a display panel according to an embodiment of the present disclosure.

FIG. 11 is a detailed cross-sectional view of a part of a display device according to an embodiment of the present disclosure.

FIG. 12 is a plan view illustrating one pixel of a display panel according to an embodiment of the present disclosure.

FIG. 13 is a plan view of a display device according to an embodiment of the present disclosure.

FIG. 14 is a plan view illustrating a disposition relationship between pixels and microlenses in area II illustrated in FIG. 13.

FIG. 15 is a view illustrating an enlarged image after passing through a micro lens array layer illustrated in FIG. 14.

FIGS. 16 and 17 are diagrams for explaining an increase in external light emitting efficiency in a display device according to an embodiment of the present disclosure.

FIG. 18 is a diagram for explaining a light emission profile in a display device according to an embodiment.

FIG. 19 is a cross-sectional view illustrating a head mounted display device including the display devices illustrated in FIGS. 4 to 7.

FIG. 20 is a cross-sectional view of a head mounted display device including the display devices illustrated in FIGS. 11 and 12.

### DETAILED DESCRIPTION

Embodiments of the present disclosure will be described more fully hereinafter with reference to the accompanying drawings. Like reference numerals may refer to like elements throughout the accompanying drawings.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

The phrase “in a plan view” means when an object portion is viewed from above, and the phrase “in a schematic cross-sectional view” means when a schematic cross-section taken by vertically cutting an object portion is viewed from the side.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” the another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to the another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein are inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

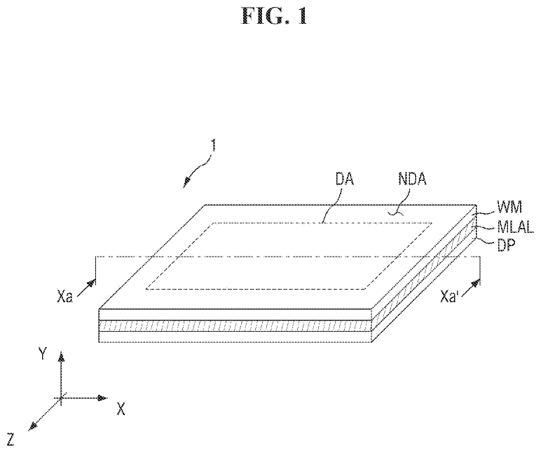

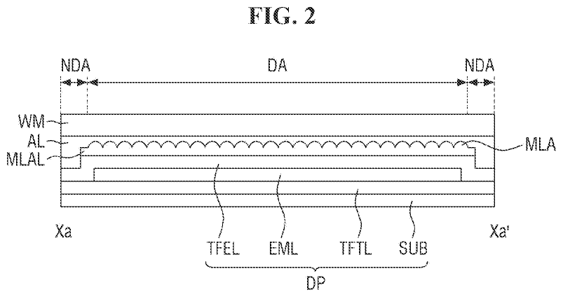

FIG. 1 is a perspective view illustrating a display device according to an embodiment of the present disclosure. FIG. 2 is a cross-sectional view of the display device taken along line Xa-Xa′ of FIG. 1.

Referring to FIGS. 1 and 2, a display device 1 includes a display panel DP, a window WM, and a micro lens array layer MLAL.

The display panel DP may be a rigid display panel or a flexible display panel. In the case of a flexible display panel, the shape of the display panel DP may be deformable by an operation such as, for example, bending, folding, or rolling. In an embodiment of the present disclosure, the display panel DP may be a display panel including an organic light emitting element.

A display area DA and a non-display area NDA may be defined in the display panel DP. The display area DA is an area where an image is displayed, and the non-display area NDA is an area adjacent to the display area DA and is an area where an image is not displayed. The non-display area NDA may surround the display area DA, but this is shown only as an example. In an embodiment, the non-display area NDA may be adjacent to only some of the edges of the display area DA. However, embodiments are not limited thereto.

The display panel DP includes a substrate SUB, a thin film transistor layer TFTL, a light emitting element layer EML, and a thin film encapsulating layer TFEL disposed on the substrate SUB.

The substrate SUB may be made of an insulating material such as, for example, glass, quartz, or polymer resin. Examples of polymeric materials include polyethersulphone (PES), polyacrylate (PA), polyacrylate (PAR), polyetherimide (PEI), polyethylene naphtholate (PEN), polyethylene terephthalate (PET), polyphenylene sulfide (PPS), polyallylate, polyimide (PI), polycarbonate (PC), cellulose triacetate: CAT), cellulose acetate propionate: CAP), or a combination thereof. Alternatively, the substrate SUB may include a metal material.

The substrate SUB may be a rigid substrate or a flexible substrate capable of being bent, folded, or rolled. When the substrate SUB is a flexible substrate, it may be formed of polyimide PI, but is not limited thereto.

The thin film transistor layer TFTL may be disposed on the substrate SUB. Not only the thin film transistors of each pixel, but also scan lines, data lines, power supply lines, scan control lines, routing lines connecting pads and data lines, and the like, may be formed in the thin film transistor layer TFTL. Each of the thin film transistors may include a gate electrode, a semiconductor layer, a source electrode, and a drain electrode.

The thin film transistor layer TFTL may be disposed in the display area DA and the non-display area NDA. For example, thin film transistors, scan lines, data lines, and power supply lines of each of the pixels of the thin film transistor layer TFTL may be disposed in the display area DA. Scan control lines and link lines of the thin film transistor layer TFTL may be disposed in the non-display area NDA.

The light emitting element layer EML may be disposed on the thin film transistor layer TFTL. The light emitting element layer EML may include pixels including a first electrode, an emitting layer, and a second electrode, and a bank defining the pixels. The light emitting layer may be an organic light emitting layer containing an organic material. In this case, the light emitting layer may include a hole transporting layer, an organic light emitting layer, and an electron transporting layer. When a predetermined voltage is applied to the first electrode and a cathode voltage is applied to the second electrode through the thin film transistor of the thin film transistor layer TFTL, holes and electrons move to the organic light emitting layer through the hole transport layer and the electron transport layer, respectively, and combine with each other in the organic light emitting layer to emit light. Pixels of the light emitting element layer EML may be disposed in the display area DA.

The thin film encapsulating layer TFEL may be disposed on the light emitting element layer EML. The thin film encapsulating layer TFEL serves to prevent oxygen or moisture from permeating into the light emitting element layer EML. To this end, the thin film encapsulating layer TFEL may include at least one inorganic layer. The inorganic layer may be, for example, a silicon nitride layer, a silicon oxy nitride layer, a silicon oxide layer, a titanium oxide layer, or an aluminum oxide layer, but is not limited thereto. In addition, the thin film encapsulating layer TFEL may serve to protect the light emitting element layer EML from foreign substances such as dust. To this end, the thin film encapsulating layer TFEL may include at least one organic layer. The organic layer may be, for example, an acrylic resin, an epoxy resin, a phenolic resin, a polyamide resin, or a polyimide resin, but is not limited thereto.

The thin film encapsulating layer TFEL may be disposed in both the display area DA and the non-display area NDA. For example, the thin film encapsulating layer TFEL may cover the light emitting element layer EML in the display area DA and the non-display area NDA, and may cover the thin film transistor layer TFT in the non-display area NDA.

The window WM is disposed on the display panel DP and may be optically transparent. Accordingly, an image generated by the display panel DP may pass through the window WM.

A micro lens array layer MLAL may be disposed between the display panel DP and the window WM. The micro lens array layer MLAL is disposed between the thin film transistor layer TFTL of the pixel and the window WM. The micro lens array layer MLAL may include a plurality of micro lenses MLA respectively corresponding to a plurality of pixels.

Each of the plurality of micro lenses MLA has a predetermined radius of curvature, magnifies an image output from the display panel DP, and then projects the enlarged image onto a virtual surface.

The window WM may be attached to the micro lens array layer MLAL by a adhesive layer AL such as, for example, an optically clear adhesive (OCA) film. The adhesive layer AL may be, for example, an optically clear adhesive (OCA) film, an optically clear resin (OCR), or a pressure sensitive adhesive film (PSA).

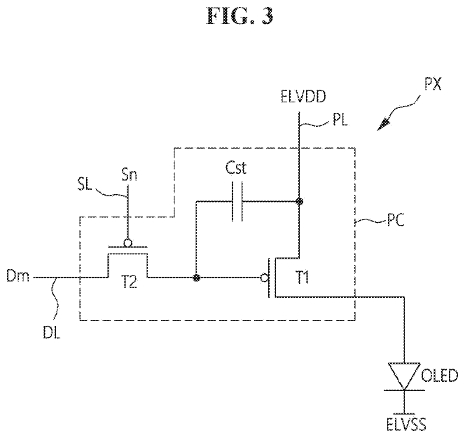

FIG. 3 is an equivalent circuit diagram of any one pixel included in a display device according to an embodiment of the present disclosure.

Referring to FIG. 3, a pixel PX may include a pixel circuit PC and a display element connected to the pixel circuit PC, for example, an organic light emitting diode OLED. The pixel circuit PC may include a first thin film transistor T1, a second thin film transistor T2, and a storage capacitor Cst. Each pixel may emit, for example, red, green, or blue light through the organic light emitting diode OLED, or may emit red, green, blue, or white light.

The second thin film transistor T2 is a switching thin film transistor and is connected to a scan line SL. Also, the second thin film transistor T2 may transmit the data voltage or data signal Dm input from a data line DL according to the switching voltage or switching signal Sn input from the scan line SL to the first thin film transistor T1. The storage capacitor Cst is connected to the second thin film transistor T2 and the driving voltage line PL, and may store a voltage corresponding to a difference between the voltage received from the second thin film transistor T2 and a first power voltage ELVDD supplied to a driving voltage line PL.

The first thin film transistor T1 is a driving thin film transistor and is connected to the driving voltage line PL and the storage capacitor Cst. Also, the first thin film transistor T1 may control the driving current flowing through the organic light emitting diode OLED from the driving voltage line PL in response to the voltage value stored in the storage capacitor Cst. The organic light emitting diode OLED may emit light having a predetermined luminance by a driving current. A counter electrode (e.g., a cathode) of the organic light emitting diode OLED may receive a second power supply voltage ELVSS.

FIG. 3 illustrates that the pixel circuit PC includes two thin film transistors and one storage capacitor, but the number of thin film transistors and the number of storage capacitors may be variously changed according to the design of the pixel circuit PC according to embodiments of the present disclosure.

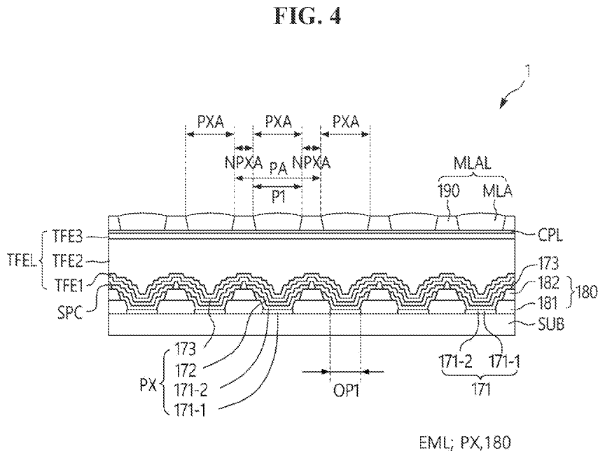

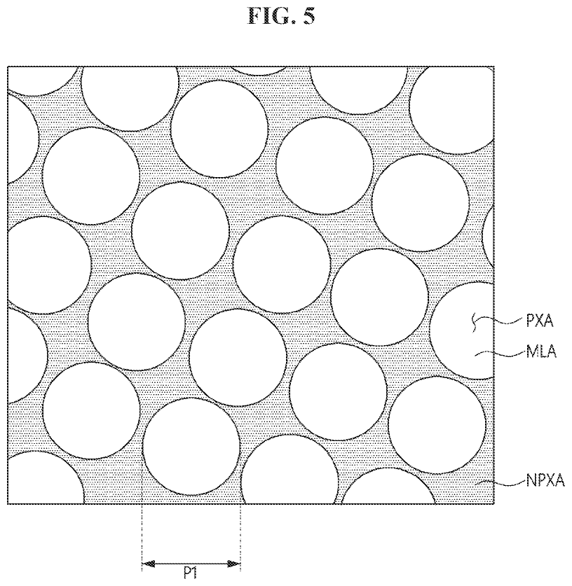

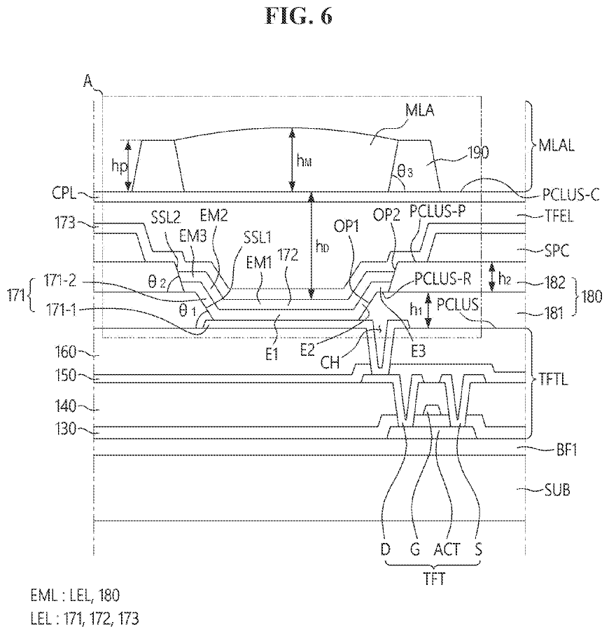

FIG. 4 is a detailed cross-sectional view of a part of the display device of FIG. 1. FIG. 5 is a cross-sectional view of a micro lens array layer. FIG. 6 is a cross-sectional view illustrating one pixel of a display panel according to an embodiment of the present disclosure.

Referring to FIGS. 4 to 6, the thin film transistor layer TFTL is formed on the substrate SUB. The thin film transistor layer TFTL includes thin film transistors TFT, a gate insulating layer 130, an interlayer insulating layer 140, a protective layer 150, and a planarization layer 160.

A buffer layer BF1 may be formed on one surface of the substrate SUB. The buffer layer BF1 may also be referred to as a buffer film BF1. The buffer film BF1 may be formed on one surface of the substrate SUB and may protect the thin film transistors TFT and a light emitting layer 172 of the light emitting element layer EML from moisture penetrating through the substrate SUB, which is vulnerable to moisture permeation. The buffer layer BF1 may be made of a plurality of inorganic layers alternately stacked. For example, the buffer layer BF1 may be formed of a multilayer in which one or more inorganic layers of a silicon nitride layer, a silicon oxynitride layer, a silicon oxide layer, a titanium oxide layer, and an aluminum oxide layer are alternately stacked. In an embodiment, the buffer layer BF1 may be omitted.

A thin film transistor TFT is formed on the buffer film BF1. The thin film transistor TFT includes an active layer ACT, a gate electrode G, a first electrode S, and a second electrode D. For example, the first electrode S may be a source electrode and the second electrode D may be a drain electrode. FIG. 6 illustrates that the thin film transistor TFT is formed in a top gate method in which the gate electrode G is positioned on the active layer

ACT, but it should be noted that the present disclosure is not limited thereto. That is, the thin film transistor TFT may be formed in a bottom gate method in which the gate electrode G is positioned below the active layer ACT, or may be formed in a double gate method in which the gate electrode G is positioned both above and below the active layer ACT, according to embodiments of the present disclosure.

The active layer ACT is formed on the buffer layer BF1. The active layer ACT may include, for example, polycrystalline silicon, single crystal silicon, low temperature polycrystalline silicon, amorphous silicon, or an oxide semiconductor. For example, oxide semiconductors may include binary compounds (ABₓ), ternary compounds (ABₓC_{y}), and quaternary compounds (ABₓC_{y}D_{z}) containing indium, zinc, gallium, tin, titanium, aluminum, hafnium (Hf), zirconium (Zr), magnesium (Mg), and the like. For example, the active layer ACT may include ITZO (oxide containing indium, tin, and zinc) or IGZO (oxide containing indium, gallium, and zinc). A light blocking layer may be formed between the buffer layer BF1 and the active layer ACT and may block external light from incident on the active layer ACT.

The gate insulating layer 130 may be formed on the active layer ACT. The gate insulating layer 130 may be formed of an inorganic layer such as, for example, a silicon nitride layer, a silicon oxy nitride layer, a silicon oxide layer, a titanium oxide layer, or an aluminum oxide layer.

The gate electrode G and a gate line may be formed on the gate insulating layer 130. The gate electrode G and the gate line may be formed as a single layer or multiple layers made of any one of, for example, molybdenum (Mo), aluminum (Al), chromium (Cr), gold (Au), titanium (Ti), nickel (Ni), neodymium (Nd), and copper (Cu) or an alloy thereof.

The interlayer insulating layer 140 may be formed on the gate electrode G and the gate line. The interlayer insulating layer 140 may be formed of an inorganic layer such as, for example, a silicon nitride layer, a silicon oxy nitride layer, a silicon oxide layer, a titanium oxide layer, or an aluminum oxide layer.

The first electrode S and the second electrode D may be formed on the interlayer insulating layer 140. Each of the first electrode S and the second electrode D may be connected to the active layer ACT through a contact hole penetrating the gate insulating layer 130 and the interlayer insulating layer 140. The first electrode S and the second electrode D may be formed as a single layer or multiple layers made of any one of, for example, molybdenum (Mo), aluminum (Al), chromium (Cr), gold (Au), titanium (Ti), nickel (Ni), neodymium (Nd), and copper (Cu) or an alloy thereof.

The protective layer 150 may be formed on the first electrode S and the second electrode D and may insulate the thin film transistor TFT. The protective layer 150 may be formed of, for example, an inorganic layer, for example, a silicon nitride layer, a silicon oxy nitride layer, a silicon oxide layer, a titanium oxide layer, or an aluminum oxide layer.

The planarization layer 160 may be formed on the protective layer 150 and may flatten a level difference caused by the thin film transistor TFT. The planarization layer 160 may be formed of an organic layer such as, for example, acrylic resin, epoxy resin, phenolic resin, polyamide resin, or polyimide resin.

The light emitting element layer EML may be disposed on the planarization layer 160. The light emitting element layer EML may include light emitting elements LEL and a bank 180. Each of the light emitting elements LEL includes a pixel electrode 171, the light emitting layer 172, and a common electrode 173. The common electrode 173 may be commonly connected to a plurality of light emitting elements LEL. Each of the light emitting elements LEL may also be referred to herein as a sub-pixel.

The pixel electrode 171 and the bank 180 may be formed on the planarization layer 160.

The pixel electrode 171 may be an anode electrode in an embodiment. When the pixel electrode 171 is the anode electrode, the pixel electrode 171 may include a reflective material. The reflective material may include one or more reflective films including such as, for example, silver (Ag), magnesium (Mg), chromium (Cr), gold (Au), platinum (Pt), nickel (Ni), copper (Cu), tungsten (W), and aluminum (Al), and may include transparent or translucent electrode formed on the reflective film in an embodiment.

Here, the transparent or translucent electrode may include at least one of, for example, ITO (Indium Tin Oxide), IZO (Indium Zinc Oxide), ZnO (Zinc Oxide), In₂O₃ (Indium, Oxide), IGO (Indium Gallium Oxide) and AZO (Aluminum Zinc Oxide).

The pixel electrode 171 includes a first pixel electrode 171-1 and a second pixel electrode 171-2.

A contact hole CH may be formed in the planarization layer 160. The contact hole CH may expose the second electrode D of the thin film transistor TFT. The first pixel electrode 171-1 may be connected to the second electrode D of the thin film transistor TFT through the contact hole CH.

The second pixel electrode 171-2 is disposed between the first pixel electrode 171-1 and the light emitting layer 172. Prior to a detailed description of the second pixel electrode 171-2, the bank 180 will be described.

The bank 180 may be disposed on the thin film transistor layer TFTL. The bank 180 may include a first bank 181 and a second bank 182. The second bank 182 may have an upper surface PCLUS-P.

The first bank 181 may include an inner surface SSL1 defining a first opening OP1. The inner surface SSL1 of the first bank 181 may have a gentle slope with respect to the upper surface of the substrate SUB. The second pixel electrode 171-2 and the light emitting layer 172 may be disposed on the inner surface SSL1. The inner surface SSL1 of the first bank 181 may have a gentle slope with respect to the upper surface of the substrate 100, allowing for the light emitting layer 172 to have a substantially constant thickness on the inner surface SSL1 of the first bank 181.

The first bank 181 may be formed to have a first height h1. Here, the first height h1 may be about 0.5 μm to about 2 μm, but is not limited thereto.

The pixel electrode 171 may be disposed in the openings OP1 and OP2 and may extend along the inner surface SSL1 of the first bank 181. The light emitting layer 172 may extend along the inner surface SSL1 of the first bank 181 on the pixel electrode 171.

A first internal angle θ1 between the inner surface SSL1 of the first bank 181 and an upper surface PCLUS of the thin film transistor layer TFTL may be an acute angle in an embodiment. The first internal angle θ1 may depend on the first height h₁ of the first bank 181. For example, the first internal angle θ1 between the inner surface SSL1 of the first bank 181 and the upper surface PCLUS of the thin film transistor layer TFTL may be about 40 degrees or less. In this case, the upper surface PCLUS of the thin film transistor layer TFTL may be a surface at which the thin film transistor layer TFTL and the first bank 181 face each other.

The first bank 181 is not formed on the entire surface of the planarization layer 160, and may expose at least a portion of the first pixel electrode 171-1 including the first opening OP1 in an embodiment. The first bank 181 may cover an end of the first pixel electrode 171-1 and the first opening OP1 may be disposed to correspond to the light emitting element LEL. For example, the light emitting element LEL may be disposed in the first opening OP1.

Although FIG. 6 illustrates one first opening OP1, a plurality of first openings OP1 may be disposed in the light emitting element layer EML as shown in FIG. 4 in an embodiment. The first bank 181 may be formed in a spaced area between the plurality of first pixel electrodes 171-1 adjacent to each other formed on the planarization layer 160.

The first bank 181 may be formed of an organic layer such as, for example, acryl resin, epoxy resin, phenolic resin, polyamide resin, or polyimide resin.

The second bank 182 may be disposed on the first bank 181. The second bank 182 may include a second opening OP2. Also, the second bank 182 may include an inner surface SSL2 defining the second opening OP2. The second opening OP2 may be disposed to correspond to the light emitting element LEL.

The second opening OP2 formed by the second bank 182 may have a wider width than the first opening OP1 formed by the first bank 181. The width of the first opening OP1 may be defined as the shortest distance between the inner surface SSL1 of the first bank 181, and the width of the second opening OP2 may be defined as the shortest distance between the inner surface SSL2 of the second bank 182.

In addition, the inner surface SSL2 of the second bank 182 may have a gentle slope with respect to the upper surface of the substrate SUB.

The second bank 182 may be formed to have a second height h₂ in an embodiment. The second height h₂ of the second bank is equal to or smaller than the first height h₁ of the first bank 181. Here, the second height h₂ may be about 0.5 μm to about 2 μm, but is not limited thereto.

A second internal angle θ2 between the inner surface SSL2 of the second bank 182 and the upper surface PCLUS-R of the first bank 181 may be the acute angle. The second internal angle θ2 may depend on the second height h₂ of the second bank 182. The second internal angle θ2 between the inner surface SSL2 of the second bank 182 and the upper surface PCLUS-R of the first bank 181 may be greater than or equal to the first internal angle θ1 between the inner surface SSL1 of the first bank 181 and the upper surface PCLUS of the thin film transistor layer TFTL. For example, the second internal angle θ2 between the inner surface SSL2 of the second bank 182 and the upper surface PCLUS-R of the first bank 181 may be in the range of about 30 degrees to about 50 degrees. In this case, the upper surface PCLUS-R of the first bank 181 may be a surface at which the first bank 181 and the second bank 182 face each other.

The second bank 182 may be formed of an organic material such as, for example, acryl resin, epoxy resin, phenolic resin, polyamide resin, or polyimide resin. The second bank 182 may be formed of the same material as the first bank 181.

The second pixel electrode 171-2 may be extended along the inner surface SSL1 of the first bank 181.

The second pixel electrode 171-2 may include a first electrode area E1, a second electrode area E2, and a third electrode area E3 in an embodiment.

The first electrode area E1 may be disposed inside the first opening OP1. The first electrode area E1 may be disposed on the first pixel electrode 171-1 and may be electrically connected to the first pixel electrode 171-1. The second electrode area E2 may be an area extending from the first electrode area E1. The second electrode area E2 may be disposed on the inner surface SSL1 of the first bank 181. The third electrode area E3 may be an area extending from the second electrode area E2. The third electrode area E3 may cover at least a portion of the upper surface PCLUS-R of the first bank 181 exposed by the second opening OP2. The third electrode area E3 may be formed not to cover the second bank 182.

In an embodiment, the second pixel electrode 171-2 may be formed not overlaping a light control layer 190, which is described in further detail below.

The light emitting layer 172 may be disposed on the second pixel electrode 171-2 and the second bank 182. The light emitting layer 172 may be disposed on an area of the second pixel electrode 171-2 exposed through the opening OP2 of the second bank 182. That is, the light emitting layer 172 may overlap the second opening OP2 of the second bank 182. The light emitting layer 172 may cover at least a portion of the opening OP2 of the second bank 182 in an embodiment.

The light emitting layer 172 may include a first light emitting layer area EM1 and a second light emitting layer area EM2 in an embodiment. The first emitting layer area EM1 may be disposed on the first electrode area E1. The second emitting layer area EM2 may be disposed on the second electrode area E2. That is, the second emitting layer area EM2 may be extended along the inner surface SSL1 of the first bank 181 on the second pixel electrode 171-2. In some embodiments, the light emitting layer 172 may further include a third light emitting layer area EM3 extending from the second light emitting layer area EM2 and disposed on the third electrode area E3. The third light emitting layer area EM3 may completely cover the third electrode area E3 of the second pixel electrode 171-2. At least a portion of the third light emitting layer area EM3 may overlap a light control layer 190, which is described further below.

Among the light emitted from the third light emitting layer area EM3, light that is not emitted to the upper surface is reflected using the second pixel electrode 171-2 to emit light to the upper surface.

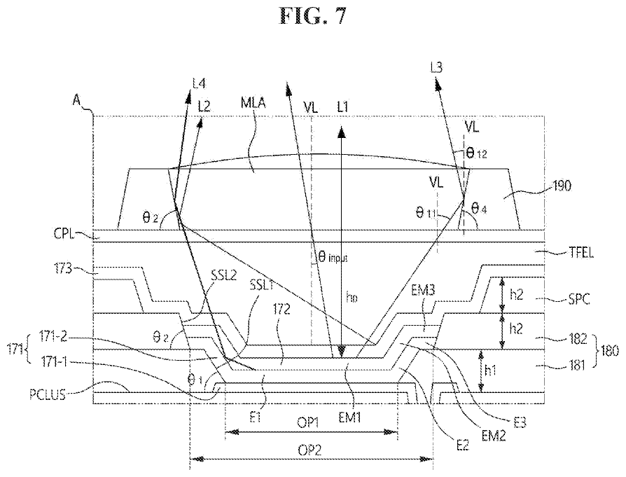

A portion of light L4 (see FIG. 7) generated from the light emitting layer 172 may travel toward the first bank 181 (i.e., toward the side of the second pixel electrode 171-2) without going upward of the second pixel electrode 171-2.

The second pixel electrode 171-2 may reflect light traveling toward a side surface of the second pixel electrode 171-2 without going upward of the second pixel electrode 171-2. That is, since the side light of the light emitting layer 172 is not lost and may be guided to proceed upward, light extraction efficiency may be improved and high light emitting efficiency may be provided.

The light emitting layer 172 may emit one of red light, green light, and blue light in an embodiment. The wavelength of red light may be about 620 nm to about 750 nm, and the wavelength of green light may be about 495 nm to about 570 nm. Also, the wavelength of blue light may be about 450 nm to about 495 nm.

In an embodiment, the light emitting layer 172 may emit white light. When the light emitting layer 172 emits white light, the light emitting layer 172 may have a stacked structure of a red light emitting layer, a green light emitting layer, and a blue light emitting layer in an embodiment. In addition, separate color filters for displaying red, green, and blue colors may be further included.

In an embodiment, the light emitting layer 172 may have a multilayer structure including a hole transporting layer, an organic light emitting layer, and an electron transporting layer.

The common electrode 173 may be disposed on the light emitting layer 172 and the second bank 182. The common electrode 173 may be entirely formed on the light emitting layer 172 and the second bank 182 in an embodiment. The common electrode 173 may be a common layer commonly formed in all light emitting elements LEL. The common electrode 173 may be a cathode electrode in an embodiment. The common electrode 173 may include one or more materials such as, for example, Li, Ca, Lif/Ca, LiF/Al, Al, Ag, and Mg. Also, the common electrode 173 may be formed of a thin metal film having a low work function. The common electrode 173 may be a transparent or translucent electrode including at least one of, for example, indium tin oxide (ITO), indium zinc oxide (IZO), zinc oxide (ZnO), indium oxide (In₂O₃), indium gallium oxide (IGO), and aluminum zinc oxide (AZO).

In the light emitting structure composed of the pixel electrode 171, the light emitting layer 172 and the common electrode 173, the common electrode 173 may be formed of a transparent conductive oxide (TCO) such as, for example, indium tin oxide (ITO) and indium zinc oxide (IZO) capable of transmitting light, or a semi-transmissive conductive material such as, for example, magnesium (Mg), silver (Ag), or an alloy of magnesium (Mg) and silver (Ag). When the common electrode 173 is formed of a transflective metal material, light emission efficiency may be increased by a micro cavity.

A spacer SPC may be further disposed between the second bank 182 and the common electrode 173. One surface of the spacer SPC may contact the second bank 182 and the other surface of the spacer SPC may contact the common electrode 173. The spacer SPC may maintain a gap between the second bank 182 and the common electrode 173. The spacer SPC may be made of an organic material or an inorganic material. For example, the spacer SPC may be made of an organic material such as photoresist, polyacrylic resin, polyimide resin, or acrylic resin. In an embodiment, the spacer SPC is not included.

An thin film encapsulating layer TFEL may be disposed on the common electrode 173. The thin film encapsulating layer TFEL may include at least one inorganic film, which may prevent penetration of oxygen or moisture into the light emitting layer 172 and the common electrode 173. Also, the thin film encapsulating layer TFEL may include at least one organic layer, which may protect the light emitting element layer EML from foreign substances such as dust. For example, the thin film encapsulating layer TFEL may include the first inorganic layer TFE1 disposed on the common electrode 173, the organic layer TFE2 disposed on the first inorganic layer TFE1, and the second inorganic layer TFE3 disposed on the organic layer TFE2. The first inorganic layer TFE1 and the second inorganic layer TFE3 may be formed of, for example, a silicon nitride layer, a silicon oxy nitride layer, a silicon oxide layer, a titanium oxide layer, or an aluminum oxide layer, but are not limited thereto. The organic layer may be formed of, for example, acrylic resin, epoxy resin, phenolic resin, polyamide resin, polyimide resin, or the like, but is not limited thereto.

A second buffer layer may be formed on the thin film encapsulating layer TFEL.

The second buffer layer may include a plurality of inorganic layers alternately stacked. For example, the second buffer layer may be formed of a multilayer in which one or more inorganic layers of, for example, a silicon nitride layer, a silicon oxynitride layer, a silicon oxide layer, a titanium oxide layer, and an aluminum oxide layer are alternately stacked. The second buffer layer may be omitted.

A capping layer CPL may be formed on the thin film encapsulating layer TFEL.

The capping layer CPL may cover the entire thin film encapsulating layer TFEL. The capping layer CPL may be made of an organic material having a high refractive index, and the wavelength of light moving along the capping layer CPL is amplified by surface plasma resonance. As a result, the intensity of the peak is increased, thereby improving light extraction efficiency in the top emission type display device. In some embodiments, the capping layer CPL may be omitted.

The plurality of micro lenses MLA and a light control layer 190 may be formed on the capping layer CPL.

The plurality of micro lenses MLA may be spaced apart from each other. The light control layer 190 is formed adjacent to the micro lens MLA. The light control layer 190 may be disposed on a plane and may surround the micro lens MLA. The micro lens MLA and the light control layer 190 may be alternately disposed at the surface of the first display unit 1. Each of the plurality of micro lenses MLA may overlap the light emitting layer 172.

Each of the plurality of micro lenses MLA may have a convex lens shape convexly protruding from the upper surface of the capping layer CPL or the upper surface of the thin film encapsulating layer TFEL. That is, each of the plurality of micro lenses MLA may have a circular shape when viewed from the plane. That is, each of the plurality of micro lenses MLA may have a hemispherical protruding shape. However, the shape of the micro lens MLA is not limited thereto. For example, each of the plurality of micro lenses MLA may have a polygonal or elliptical shape on the plane. Also, each of the plurality of micro lenses MLA may have a symmetrical or asymmetrical structure. In addition, in FIG. 5, each of the plurality of micro lenses MLA is illustrated as having the same size as each other. However, embodiments are not limited thereto. For example, in an embodiment, each of the plurality of micro lenses MLA may have different sizes.

Each of the plurality of micro lenses MLA may be made of, for example, acrylic resin or the like, and may be formed on the thin film encapsulating layer TFEL through, for example, a photo process or an imprinting process.

The size of each of the plurality of micro lenses MLA may be reduced to a pixel size by directly forming the plurality of micro lenses MLA on the display panel DP. Also, the distance between the micro lens MLA and the focal plane (e.g., the focal length) decreases as the size of the micro lens MLA decreases. In an embodiment of the present disclosure, the distance between the micro lens MLA and the focal length may be about 30 μm or less. Here, the distance hD between the micro lens MLA and the light emitting layer 172 may be about 1.5 μm to about 10 μm.

Each pixel area PA of the display panel DP may include a light emitting area PXA and a non-light emitting area NPXA. The light emitting area PXA may be an area in which the light emitting layer 172 for actually outputting light is disposed among each pixel area PA, and the non-light emitting area NPXA is adjacent to the light emitting area PXA. The non-light emitting area NPXA may be a light blocking area adjacent to the light emitting area PXA and may include a light blocking material such as a black matrix. In an embodiment, the light emitting area PXA may be formed wider than the first opening OP1 defined by the first bank 181.

The plurality of micro lenses MLA may be disposed to correspond to each of the plurality of pixel areas PA. That is, each of the plurality of micro lenses MLA may overlap the light emitting area PXA of the corresponding pixel area PA. As shown in FIG. 4, each of the plurality of micro lenses MLA may be disposed to correspond to the light emitting area PXA of the corresponding pixel area PA. Also, as shown in FIGS. 5 and 6, the plurality of micro lenses MLA may have a convex lens shape protruding convexly from the upper surface of the thin film encapsulating layer TFEL or the capping layer CPL. That is, each of the plurality of micro lenses MLA may have a circular shape when viewed from the plane. That is, each of the plurality of micro lenses MLA may have the hemispherical protruding shape. However, the shape of the micro lens MLA is not limited thereto. For example, each of the plurality of micro lenses MLA may have a polygonal or elliptical shape on the plane according to embodiments. Also, each of the plurality of micro lenses MLA may have a symmetrical or asymmetrical structure.

In addition, the micro lens MLA may have the same size, or the micro lenses MLA may have different sizes, according to embodiments of the present disclosure.

Each of the plurality of micro lenses MLA may be designed to have a focal point focused on corresponding pixels PX. A width P1 of each of the plurality of micro lenses MLA according to an example of the present disclosure may correspond to the size of the light emitting area PXA. The width P1 of each of the plurality of micro lenses MLA may have a size corresponding to the diameter of the micro lens MLA.

In an embodiment, the width P1 of each of the plurality of micro lenses MLA may be greater than that of the second opening OP2. The micro lens MLA may have a diameter of about 10 μm or more.

In addition, each micro lens MLA may be focused on a corresponding pixel PX by adjusting the curvature radius and height of each micro lens MLA. For example, each of the plurality of micro lenses MLA may have a curvature of about 0.05 to about 0.2. In an embodiment, each of the plurality of micro lenses MLA may have a curvature of about 0.12 to about 0.2. However, embodiments of the present disclosure are not limited thereto. The thickness hM of the micro lens MLA may be formed to be about 2 μm to about 3.5 μm in an embodiment, but is not limited thereto.

In addition, each of the plurality of micro lenses MLA may be disposed to correspond to the light emitting area PXA of the corresponding pixel area PA. Therefore, if each micro lens MLA is formed to the non-light emitting area NPXA, a screen door effect in which the non-light emitting area NPXA is recognized by the user's eyes may occur, because the non-light emitting area NPXA is enlarged when the image output from the pixel PX is enlarged. However, the micro lenses MLA according to an embodiment of the present disclosure are disposed to correspond to each light emitting area PXA. As a result, a phenomenon in which the non-light emitting area NPXA is enlarged may be minimized or reduced.

The light control layer 190 is formed on the top surface of the capping layer CPL or the thin film encapsulating layer TFEL. The light control layer 190 may overlap the non-light emitting area NPXA of the pixel area PA. The light control layer 190 is a layer that totally reflects light emitted from the light emitting layer 172 in a lateral direction rather than an upper direction (Z-axis direction) to proceed in an upper direction (Z-axis direction). The light control layer 190 overlaps the second bank 182 and does not overlap the light emitting area PXA.

The light control layer 190 may include an inclined surface having a predetermined inclination angle θ3 on a surface in contact with the micro lens MLA. A taper angle θ3 of the inclined surface, that is, the inclined angle, may be formed to be about 60 degrees or more and about 90 degrees or less, but is not limited thereto. The taper angle θ3 is the inclination angle of the inclined surface of the light control layer 190, and is an angle between the upper surface

PCLUS-C of the capping layer CPL (i.e., a surface of the capping layer CPL in contact with the light control layer 190) and the side surface of the light control layer 190. In this case, the upper surface PCLUS-C of the capping layer CPL may be a surface at which the capping layer CPL and the micro lens MLA face each other.

The inclination angle θ3 of the light control layer 190 is greater than the inclination angle θ2 of the inclination surface of the second pixel electrode 171-2.

The light control layer 190 may be formed of an organic layer or an organic layer including inorganic particles. The organic layer may be, for example, an acrylic resin, an epoxy resin, a phenolic resin, a polyamide resin, or a polyimide resin, but is not limited thereto. The inorganic particles may be metal particles, but are not limited thereto.

As the thickness hp of the light control layer 190 increases, the ratio of light from the light emitting layer 172 that is totally reflected on the inclined surface of the light control layer 190 and travels upward (Z-axis direction) may increase. Therefore, the thickness hp of the light control layer 190 may be formed to be about 1.5 μm or more and less than or equal to the thickness hM of the micro lens, which may increase the light emission efficiency of the pixel PX. The step difference between the light control layer 190 and the micro lens MLA in the z direction is about 0.5 μm or more, and the thickness hM of the micro lens MLA is about 5 μm or less, for example, about 3.5 μm or less. Therefore, according to embodiments, the light control layer 190 has a thickness hp of about 1.5 μm or more and about 4.5 μm or less, e.g., about 1.5 μm or more and about 3 μm or less. The thickness hp of the light control layer 190 refers to the distance from the bottom surface of the light control layer 190 to the highest upper surface, based on FIG. 4. The thickness hM of the micro lens MLA means the distance from the bottom surface to the highest upper surface, based on FIG. 6.

The plurality of light control layers 190 may serve as reflective layer that propagates upward the light that proceeds to the side surface of the light control layer 190 among the light emitted from the plurality of light emitting element layers EML.

FIG. 7 is an enlarged view of area A of FIG. 6.

Referring to FIG. 7, the light emitted from a pixel of the display panel may include a first light L1 traveling upward from the first light emitting layer area EM1 and a second light L2 traveling toward the light control layer 190 from the second light emitting layer area EM2.

The first light L1 travels upward from the first light emitting layer area EM1, passes through the capping layer CPL and the micro lens MLA, and exits to the upper surface of the micro lens MLA.

The second light L2 emitted from the second emitting layer area EM2 travels toward the light control layer 190 and is reflected by the light control layer 190. Then, the second light L2 passes through the micro lens MLA and exits to the upper surface of the micro lens MLA.

The first angle θ1 formed with the side surface SSL1 of the first bank 181 and the upper surface PCLUS of the thin film transistor layer TFTL may be determined to prevent light emitted from the second light emitting layer area EM2 from escaping the interface between the light control layer 190 and the micro lens MLA.

A third light L3 is light that is emitted at a first light emission angle θ11 at the interface between the capping layer CPL and the micro lens MLA and is totally reflected at the interface between the light control layer 190 and the micro lens MLA and is exited at a second light emission angle θ12. Side light of the light emitting layer 172 may be refracted at an interface between the capping layer CPL and the micro lens MLA due to a difference in refractive index between the capping layer CPL and the micro lens MLA. As a result, the first light emission angle θ11 and the second light emission angle θ12 refer to an angle between a normal line VL drawn vertically upward at the interface between the capping layer CPL and the micro lens MLA and the first lightL3.

The refractive index of the light control layer 190 is smaller than that of the micro lens MLA to totally reflect light that is refracted at the interface between the capping layer CPL and the micro lens MLA, and proceeds to the light control layer 190. Here, a difference in refractive index between the light control layer 190 and the micro lens MLA may be greater than or equal to about 0.1 and less than or equal to about 0.2. The refractive index of the micro lens MLA is greater than the refractive index of the light control layer 190 and less than or equal to the refractive index of the capping layer CPL. In an embodiment, the curvature of the micro lens MLA is about 0.12, the diameter of the micro lens MLA is about 10 μm, the inclination angle of the light control layer 190 is about 70°, the inclination angle of the side of the second pixel electrode 171-2 is about 30°, the refractive index of the micro lens MLA is about 1.64, the refractive index of the light control layer 190 is about 1.53, and a difference in refractive index between the light control layer 190 and the micro lens MLA is about 0.11.

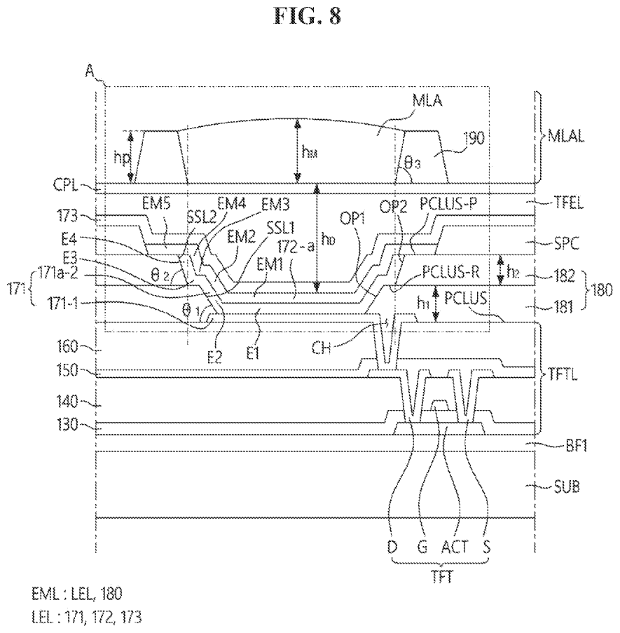

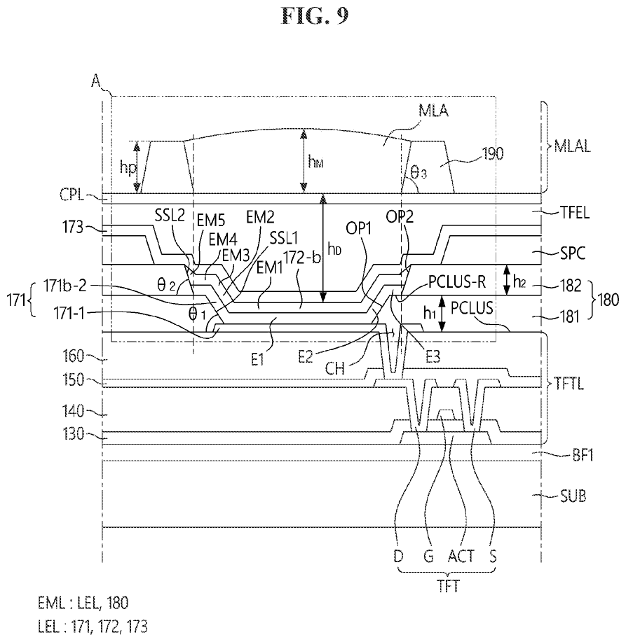

FIG. 8 is a cross-sectional view illustrating one pixel of a display panel according to an embodiment of the present disclosure. FIG. 9 is a cross-sectional view illustrating one pixel of a display panel according to an embodiment of the present disclosure.

FIGS. 8 and 9 are different from FIG. 6 in that they have second pixel electrodes 171a-2 and 171b-2 that are longer than the second pixel electrode 171-2 of FIG. 6, and have light emitting layers 172a and 172b that are longer than the light emitting layer 172 of FIG. 6. For convenience of explanation, a further description of components and technical aspects previously described with reference to FIG. 6 may be omitted.

First, referring to FIG. 8, the second pixel electrode 171a-2 may include the first electrode area E1, the second electrode area E2, the third electrode area E3, and a fourth electrode area E4.

The first electrode area E1 may be disposed inside the first opening OP1. In an embodiment, the first electrode area E1 may be disposed on the first pixel electrode 171-1 and may be electrically connected to the first pixel electrode 171-1. The second electrode area E2 may be an area extending from the first electrode area E1. The second electrode area E2 may be disposed on the inner surface SSL1 of the first bank 181. The third electrode area E3 may be an area extending from the second electrode area E2. The third electrode area E3 may cover the upper portion PCLUS-R of the first bank 181 exposed by the second opening OP2. The fourth electrode area E4 may be an area extending from the third electrode area E3. The fourth electrode area E4 may be extended along the inner surface SSL1 of the second bank 182.

In an embodiment, the fourth electrode area E4 of the second pixel electrode 171-2 is illustrated as overlapping the light control layer 190 described further below, but is not limited thereto. In an embodiment, the fourth electrode area E4 does not overlap the light control layer 190.

The light emitting layer 172-a may be disposed on the second pixel electrode 171a-2 and the second bank 182. The light emitting layer 172-a may be disposed on an area of the second pixel electrode 171a-2 exposed through the opening OP2 of the second bank 182. That is, the light emitting layer 172-a may overlap the second opening OP2 of the second bank 182. The light emitting layer 172-a may cover the opening OP2 of the second bank 182 in an embodiment.

In an embodiment, the light emitting layer 172-a may include the first light emitting layer area EM1, the second light emitting layer area EM2, the third light emitting layer area EM3, a fourth light emitting layer area EM4, and a fifth light emitting layer area EM5. The first light emitting layer area EM1 may be disposed on the first electrode area E1. The second light emitting layer area EM2 may be disposed on the second electrode area E2. That is, the second light emitting layer area EM2 may be extended along the inner surface SSL1 of the first bank 181 on the second pixel electrode 171a-2. In some embodiments, the light emitting layer 172-a may further include the third light emitting layer area EM3 extending from the second light emitting layer area EM2. The third light emitting layer area EM3 is disposed on the third electrode area E3 of the second pixel electrode 171a-2. In addition, the light emitting layer 172-a may be further extended along the inner surface SSL2 of the second bank 182. In this case, the light emitting layer 172-a may further include the fourth light emitting layer area EM4 extending from the third light emitting layer area EM3. In some embodiments, the light emitting layer 172-a may further include the fifth light emitting layer area EM5 extending from the fourth light emitting layer area EM4. The fifth light emitting layer area EM5 may cover at least a portion of an upper portion of the second bank 182. The fourth light emitting layer area EM4 and the fifth light emitting layer area EM5 may completely cover the fourth electrode area E4.

In some embodiments, the thickness of the light emitting layer 172-b of the fifth light emitting layer area EM5 may gradually decrease toward the edge of the fifth light emitting layer area EM5, as shown in FIG. 9.

In some embodiments, at least a portion of the fifth light emitting layer area EM5 may overlap the light control layer 190 described further below.

According to some embodiments, light may be emitted from the first light emitting layer area EM1 to the fourth light emitting layer area EM4, thereby expanding the light emitting area.

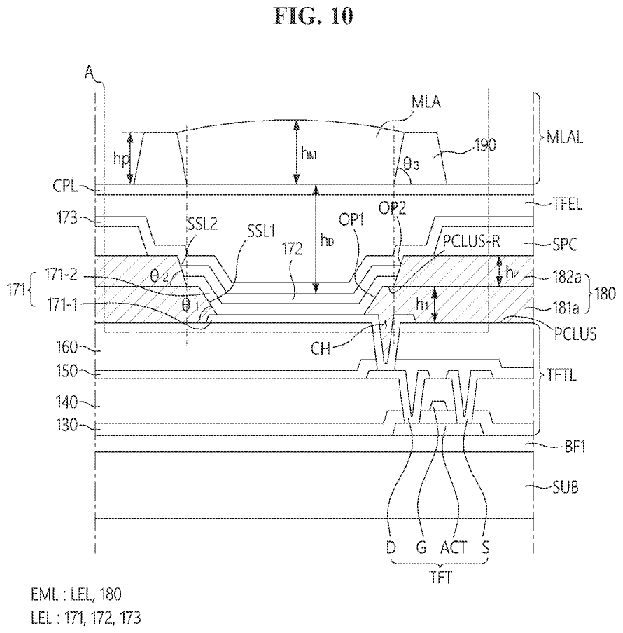

FIG. 10 is a cross-sectional view illustrating one pixel of a display panel according to an embodiment of the present disclosure. FIG. 10 is different from FIG. 6 in that the display panel and a first bank 181a and a second bank 182a of FIG. 10 include an opaque material. For convenience of explanation, a further description of components and technical aspects previously described with reference to FIG. 6 may be omitted.

The first bank 181a and the second bank 182a may include an opaque material capable of blocking light. For example, the first bank 181a and the second bank 182a may include carbon that represents black color, but are not limited thereto. In some embodiments, the first bank 181a and the second bank 182a may include a photopolymerizable compound that is cured by light irradiation such as ultraviolet light and exhibits a black color. The opaque material may be distributed over the entire area of the first bank 181 so that the first bank 181a and the second bank 182a themselves may be opaque. However, embodiments are not limited thereto, and the opaque material may be intensively distributed on the inclined surfaces (inner surfaces) of the first bank 181a and the second bank 182a according to embodiments. The first bank 181a and the second bank 182a including the opaque material may have very low light transmittance. For example, even if some of the light not reflected from the second pixel electrode 171-2 travels to the first bank 181a, the light may not pass through the first bank 181a and may be reflected again. That is, it is possible to prevent light emitted from the light emitting layer 172 to the first bank 181a from passing through the first bank 181a to be dissipated as heat inside the first bank 181a.

Although FIG. 10 illustrates that both the first bank 181a and the second bank 182a include an opaque material, embodiments are not limited thereto. Also, at least one of the first bank 181a and the second bank 182a may be implemented to include an opaque material according to embodiments. For example, only an area of the first bank 181a contacting light emitted from the light emitting layer 172 may be opaque according to embodiments.

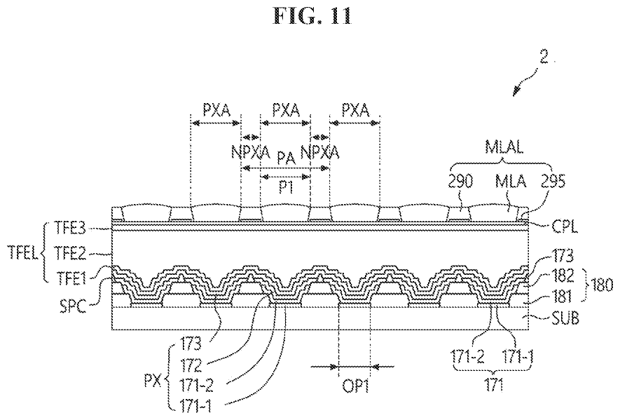

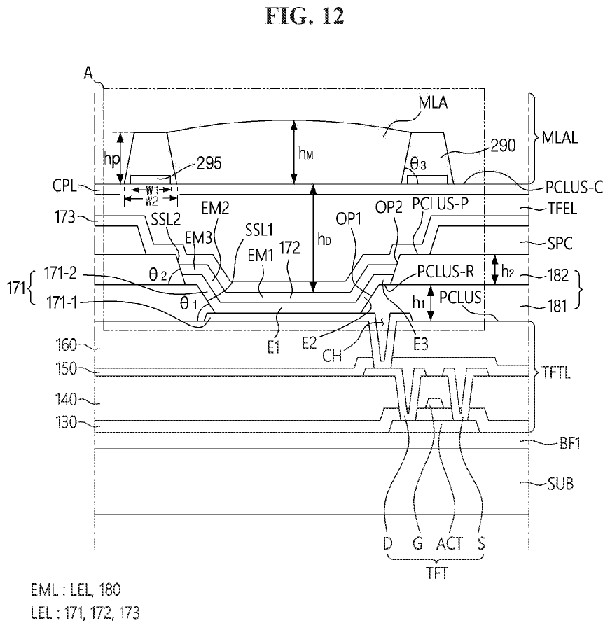

FIG. 11 is a detailed cross-sectional view of a part of a display device according to an embodiment of the present disclosure. FIG. 12 is a plan view illustrating one pixel of a display panel according to an embodiment of the present disclosure.

Referring to FIGS. 11 and 12, a second display unit 2 may include the substrate SUB, the thin film transistor layer TFTL, the light emitting element layer EML, the thin film encapsulating layer TFEL, and the micro lens array layer MLAL.

The light emitting element layer EML may include light emitting elements LEL and the bank 180. Each of the light emitting elements LEL includes the pixel electrode 171, the light emitting layer 172, and the common electrode 173. The common electrode 173 may be commonly connected to the plurality of light emitting elements LEL.

Referring to FIGS. 11 and 12, the pixel electrode 171 includes the first pixel electrode 171-1 and the second pixel electrode 171-2.

The bank 180 may include the first bank 181 and the second bank 182.

At least one of the first bank 181 and the second bank 182 may be formed of an organic material such as, for example, acrylic resin, epoxy resin, phenolic resin, polyamide resin, or polyimide resin or the like.

In an embodiment, at least one of the first bank 181 and the second bank 182 may include an opaque material capable of blocking light.

Referring back to FIGS. 11 and 12, the capping layer CPL may be further included between the thin film encapsulating layer TFEL and the micro lens array layer MLAL.

The micro lens array layer MLAL may include the plurality of micro lenses MLA, a light control layer 290, and a light blocking pattern 295.

The plurality of micro lenses MLA and the light control layer 290 may be formed on the capping layer CPL. The light blocking pattern 295 may be formed between the capping layer CPL and a light control layer 290.

The light blocking pattern 295 may be formed of a photosensitive resin capable of blocking light. For example, the light blocking pattern 295 may include an inorganic black pigment such as, for example, carbon black or an organic black pigment. The light blocking pattern 295 may have lower light transmittance than the light control layer 290. For example, the light transmittance of the light blocking pattern 295 may be about 60% or less. Therefore, in embodiments, even if some of the light not reflected from the second pixel electrode 171-2 travels to the light blocking pattern 295, the light does not pass through the light blocking pattern 295 and may be reflected again. Accordingly, the light blocking pattern 295 may prevent color mixing between adjacent light emitting areas.

The light blocking pattern 295 may be covered by the light control layer 290. That is, the light blocking pattern 295 may have a narrower width W2 than the width W1 of the light control layer 290.

The plurality of micro lenses MLA may be spaced apart from each other. The light control layer 290 is formed adjacent to the micro lens MLA. The light control layer 290 may be disposed on the plane to surround the micro lens MLA. The micro lens MLA and the light control layer 290 may be alternately disposed at the surface of the second display unit 2. Each of the plurality of micro lenses MLA may overlap the light emitting layer 172.

Each of the plurality of micro lenses MLA may have a convex lens shape convexly protruding from the upper surface of the capping layer CPL or the upper surface of the thin film encapsulating layer TFEL. That is, each of the plurality of micro lenses MLA may have a circular shape when viewed from the plane. That is, each of the plurality of micro lenses

MLA may have a hemispherical protruding shape. However, the shape of the micro lens MLA is not limited thereto. For example, each of the plurality of micro lenses MLA may have a polygonal or elliptical shape on the plane according to embodiments. Also, each of the plurality of micro lenses MLA may have a symmetrical or asymmetrical structure. In addition, the plurality of micro lenses MLA is illustrated as having the same size as each other in FIG. 11. However, embodiments are not limited thereto. For example, according to embodiments, the plurality of micro lenses MLA may have different sizes from each other.

Each of the plurality of micro lenses MLA may be made of acrylic resin or the like, and may be formed on the thin film encapsulating layer TFEL through the photo process or the imprinting process.

Each pixel area PA of the display panel DP may include a light emitting area PXA and a non-light emitting area NPXA. The light emitting area PXA is an area in which the light emitting layer 172 for actually outputting light is disposed among each pixel area PA, and the non-light emitting area NPXA is an area adjacent to the light emitting area PXA and in which the light blocking pattern 295 is disposed. In an embodiment, the light emitting area PXA may be wider than the second opening OP2 defined by the second bank 182. In a comparative example, the light emitting area may have the same size as the opening.

The plurality of micro lenses MLA may be disposed to correspond to each of the plurality of pixel areas PA. That is, each of the plurality of micro lenses MLA may overlap the light emitting area PXA of the corresponding pixel area PA. As shown in FIG. 12, each of the plurality of micro lenses MLA may be disposed to correspond to the light emitting area PXA of the corresponding pixel area PA.

Each of the plurality of micro lenses MLA may be designed to have the focal point focused on corresponding pixels PX. The width P1 of each of the plurality of micro lenses MLA according to an embodiment of the present disclosure may have a size corresponding to the light emitting area PXA. In an embodiment, the width P1 of each of the plurality of micro lenses MLA may be greater than that of the second opening OP2. The width P1 of each of the plurality of micro lenses MLA may correspond to the size of the light emitting area PXA.

In addition, the focal point of each micro lens MLA may be focused on a corresponding pixel PX by adjusting the radius of curvature and height of each micro lens MLA. Each of the plurality of micro lenses MLA may have a curvature of about 0.05 to about 0.2, e.g., about 0.12 to about 0.2. The micro lens MLA may have a thickness hM of about 2 μm to 3.5 μm.

In addition, each of the plurality of micro lenses MLA may be disposed to correspond to the light emitting area PXA of the corresponding pixel area PA. Therefore, if each micro lens MLA is formed to the non-light emitting area NPXA, the screen door effect in which the non-light emitting area NPXA is recognized by the user's eyes may occur because it is enlarged to the non-light emitting area NPXA when the image output from the pixel PX is enlarged. However, the micro lens MLA according to embodiments of the present disclosure are disposed to correspond to each light emitting area PXA. As a result, a phenomenon in which the non-light emitting area NPXA is enlarged may be minimized or reduced.

The light control layer 290 is formed on the upper surface of the capping layer CPL or the upper surface of the thin film encapsulating layer TFEL. The light control layer 290 may overlap the non-light emitting area NPXA of the pixel area PA. The light control layer 290 is a layer that totally reflects light emitted from the light emitting layer 172 in a lateral direction rather than an upper direction (Z-axis direction) to proceed in an upper direction (Z-axis direction). The light control layer 290 overlaps the second bank 182 and does not overlap the light emitting area PXA. The light emitting layer 172 may be included in the light emitting area PXA. That is, the light control layer 290 does not overlap the light emitting layer 172 in an embodiment.

The light control layer 290 may include an inclined surface having a predetermined inclined angle on a surface in contact with the micro lens MLA. The taper angle θ3 of the inclined surface may be formed to be about 70 degrees or more and about 90 degrees or less.

The taper angle θ3 is an angle of inclination of the inclined surface of the light control layer 290 and indicates an angle between the capping layer CPL and the inclined surface of the light control layer 290.

The light control layer 290 may be formed of an organic layer or an organic layer including inorganic particles. The organic layer may be, for example, an acrylic resin, an epoxy resin, a phenolic resin, a polyamide resin, or a polyimide resin, but is not limited thereto. The inorganic particles may be metal particles, but are not limited thereto.

As the thickness hp of the light control layer 290 increases, the ratio of light from the light emitting layer 172 that is totally reflected on the inclined surface of the light control layer 290 and travels upward (Z-axis direction) may increase. Therefore, the thickness hp of the light control layer 290 may be formed to be about 1.5 μm or more and less than or equal to the thickness hM of the micro lenses, which may increase the light output efficiency of the pixel PX. The step difference between the light control layer 290 and the micro lens MLA in the z direction is about 0.5 μm or more, and the thickness hM of the micro lens MLA is about 5 μm or less, e.g., about 3.5 μm or less. Therefore, in an embodiment, the light control layer 290 has the thickness hp of about 1.5 μm or more and about 4.5 μm or less, e.g., about 1.5 μm or more and about 3 μm or less. The thickness hp of the light control layer 290 refers to the distance from the bottom surface to the upper surface, based on FIG. 12. The thickness hM of the micro lens MLA means the distance from the bottom surface to the upper surface, based on FIG. 12.

The plurality of light control layers 290 propagate the light that proceeds to the side of the second pixel electrode 171-2 among the light emitted from the plurality of light emitting element layers EML to the upper part of the light emitting element layer EML, As a result, the light emitting area may be enlarged. This will be described in further detail below with reference to FIG. 11.

For convenience of explanation, a further description of components and technical aspects previously described with reference to the display panel of FIG. 6 may be omitted.

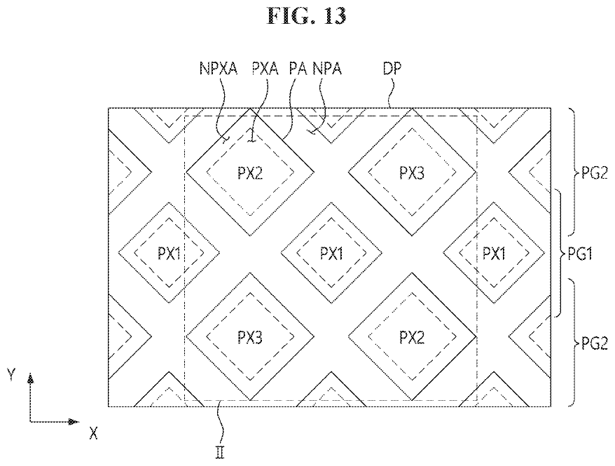

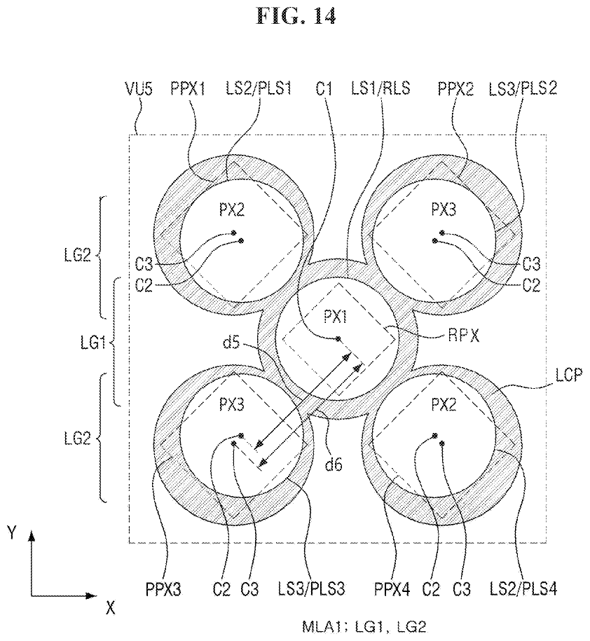

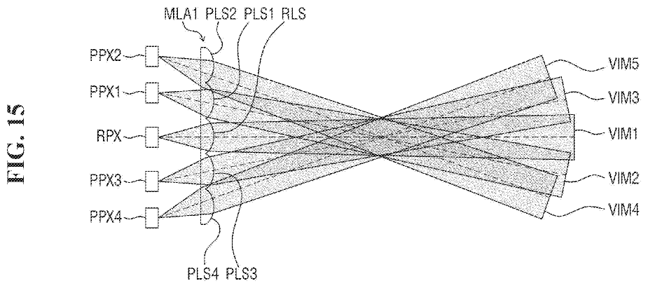

FIG. 13 is a plan view of a display device according to an embodiment of the present disclosure. FIG. 14 is a plan view illustrating a disposition relationship between pixels and microlenses in area II illustrated in FIG. 13. FIG. 15 is a view illustrating an enlarged image after passing through the micro lens array layer MLAL illustrated in FIG. 14.

Referring to FIG. 13, the display device may include a plurality of pixel groups. For example, the plurality of pixel groups may include first pixel groups PG1 and second pixel groups PG2. The first pixel groups PG1 and the second pixel groups PG2 may be alternately and repeatedly arranged along the first direction (Y direction).

The first pixel groups PG1 may include a plurality of first pixels PX1. The plurality of first pixels PX1 may be arranged along the second direction (X direction). The second pixel groups PG2 may include a plurality of second pixels PX2 and a plurality of third pixels PX3. The second pixels PX2 and the third pixels PX3 are alternately repeated and may be arranged along the second direction (X direction). A non-pixel area NPA may be defined between the first to third pixels PX1, PX2, and PX3.

The arrangement structure of the first to third pixels PX1, PX2, and PX3 illustrated in FIG. 13 is only shown as an example, and embodiments of the present disclosure are not limited thereto. For example, the first pixel PX1, the second pixel PX2, and the third pixel PX3 may be alternately arranged in a stripe shape along the second direction (X direction) in an embodiment of the present disclosure. In addition, although each of the first to third pixels PX1, PX2, and PX3 is illustrated as having a rectangular shape, embodiments are not limited thereto. For example, the shape of each of the first to third pixels PX1, PX2, and PX3 may be variously deformed into, e.g., a polygonal shape, a circular shape, an elliptical shape, or the like. In an embodiment, the first to third pixels PX1, PX2, and PX3 may have different shapes. For example, in an embodiment, the first pixel PX1 may have the circular shape, and the second and third pixels PX2 and PX3 may have the rectangular shape.

In addition, although FIG. 13 exemplarily illustrates that the size of the first pixels PX1 is smaller than the sizes of the second and third pixels PX2 and PX3, embodiments are not limited thereto. For example, the first to third pixels PX1, PX2, and PX3 may have the same size as each other in an embodiment of the present disclosure.

In an embodiment of the present disclosure, the first pixels PX1 may be green pixels, the second pixels PX2 may be blue pixels, and the third pixels PX3 may be red pixels. However, embodiments are not limited thereto.

Referring to FIGS. 13 and 14, the display device includes a micro lens array layer MLA1 configured to provide a 5-view image.

The micro lens array layer MLA1 includes a first micro lens group LG1 disposed to correspond to the first pixel group PG1 and a second micro lens group LG2 disposed to correspond to the second pixel group PG2. The first micro lens group LG1 includes first micro lenses LS1 disposed to correspond to the first pixels PX1, respectively, and the second micro lens group LG2 includes second micro lenses LS2 disposed to correspond to the second pixels PX2 and third micro lenses LS3 disposed to correspond to the third pixels PX3.

The first and second micro lens groups LG1 and LG2 are alternately and repeatedly disposed in the first direction (Y direction), and the second micro lenses LS2 and the third micro lenses LS3 are alternately and repeatedly disposed in the second direction (X direction). Each of the first to third micro lenses LS1 to LS3 may have the circular shape when viewed from the plane.

FIG. 14 exemplarily illustrates that the first to third micro lenses LS1 to LS3 have the same size. However, embodiments are not limited thereto. For example, according to embodiments, the size of the first micro lenses LS1 may be smaller than the sizes of the second and third micro lenses LS2 and LS3. That is, each of the micro lenses LS1 to LS3 may have a different size according to the size of a corresponding pixel.

When the sizes of the first to third micro lenses LS1 to LS3 are the same, the size of the light control layer LCP surrounding the first micro lenses LS1, the size of the light control layer LCP surrounding the second micro lenses LS2, and the size of the light control layer LCP surrounding the third micro lenses LS3 may be the same. Alternatively, when the sizes of the first to third micro lenses LS1 to LS3 are different from each other, the size of the light control layer LCP surrounding the first micro lenses LS1, the size of the light control layer LCP surrounding the second micro lenses LS2, and the size of the light control layer LCP surrounding the third micro lenses LS3 may be different from each other. That is, each light control layer LCP may have a different size according to the size of the corresponding micro lenses LS1 to LS3.

Referring to FIGS. 14 and 15, the micro lens array layer MLA1 enlarges an image output from a corresponding pixel. In this case, each of the micro lenses LS1 to LS3 of the micro lens array layer MLA1 may be disposed to correspond to the pixel area PA. In this case, the pixel area PA is enlarged by the micro lenses LS1 to LS3, and the non-pixel area NPA is not enlarged by the micro lens array layer MLA1. Accordingly, in embodiments of the present disclosure, the non-pixel area NPA may be prevented from being enlarged and visually recognized by the user.

The micro lenses LS1 to LS3 of the micro lens array layer MLA1 may be grouped into a plurality of viewpoint units VU5 to provide a 5-viewpoint image. Each viewpoint unit VU5 includes five micro lenses RLS and PLS1 to PLS4. In an embodiment of the present disclosure, each viewpoint unit VU5 includes a reference micro lens RLS corresponding to the reference pixel RPX and peripheral micro lenses PLS1, PLS2, PLS3 and PLS4 corresponding to the peripheral pixels PPX1 to PPX4, respectively. For example, the reference pixel RPX is the first pixel PX1, and the peripheral pixels PPX1 to PPX4 may include two second pixels PX2 and two third pixels PX3 disposed around the first pixel PX1 to the third pixel PX3. For convenience of description, four peripheral pixels are referred to as first to fourth peripheral pixels PPX1 to PPX4, and four peripheral micro lenses are referred to as first to fourth peripheral micro lenses PLS1 to PLS4.

A midpoint C1 of the reference pixel RPX may coincide with a midpoint C1 of the reference micro lens RLS. Based on the midpoint C1 of the reference micro lens RLS, a midpoint C2 of each of the first to fourth peripheral micro lenses PLS1 to PLS4 may be spaced apart at a first distance d5. Based on the midpoint C1 of the reference pixel RPX, a midpoint C3 of each of the first to fourth peripheral pixels PPX1 to PPX4 may be spaced apart from each other by a second distance d6. Here, the second distance d6 may be greater than the first distance d5. That is, the midpoint C3 of each of the first to fourth peripheral pixels PPX1 to PPX4 does not match the midpoint C2 of each of the first to fourth peripheral micro lenses PLS1 to PLS4. Accordingly, the images output from the first to fourth peripheral pixels PPX1 to PPX4 may be refracted by corresponding peripheral lenses and may be focused on the same point as the image output from the reference pixel RPX. Thus, five viewpoint images VIM1 to VIM5 may be expressed by the viewpoint unit VU5.

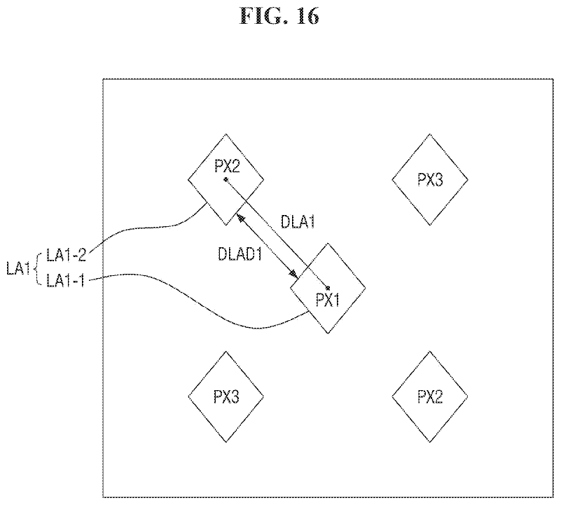

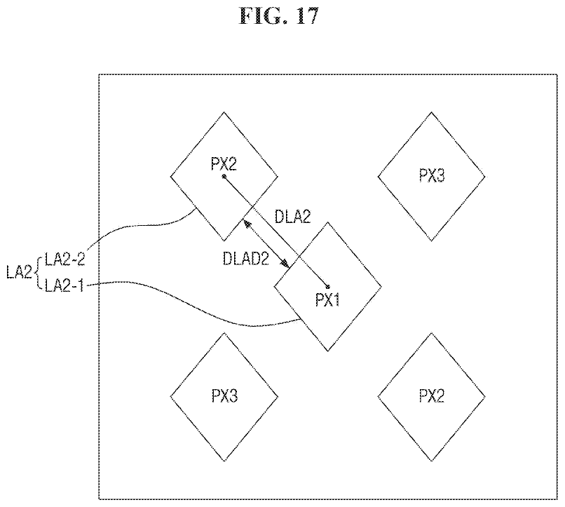

FIGS. 16 and 17 are diagrams for explaining an increase in external light emitting efficiency in a display device according to an embodiment of the present disclosure.

Here, FIG. 16 illustrates an example of the light emitting pattern in which the second pixel electrodes 171-2 and 171a-2 and the light emitting layer 172 do not extend to the second opening (OP2 in FIG. 6) for the second pixel PX2 of the display device without disposing the light control layers 190 and 290 and the micro lens MLA. FIG. 17 illustrates an example of the light emitting pattern in which the second pixel electrodes 171-2 and 171a-2 and the light emitting layer 172 extend to the second opening (OP2 in FIG. 6) for the second pixel PX2 of the display device disposing the light control layers 190 and 290 and the micro lens MLA.

Although all of the light emitting patterns are illustrated in the shape of a diamond, the light emitting patterns correspond to the shape and size of the pixel unit, and are not limited to those shown in FIGS. 16 and 17.

Comparing light emitting patterns for the same second pixel PX2 with reference to FIGS. 16 and 17, the size of the light emitting pattern LA2-1 in FIG. 17 is larger than that of the light emitting pattern LA1-1 in FIG. 16. The distance DLA1 between the center of each light emitting pattern LA1-1 corresponding to the first pixel PX1 and the center of the light emitting pattern LA1-2 corresponding to the second pixel PX2 adjacent to the first pixel PX1 is equal to the distance DLA2 between the center of each light emitting pattern LA2-1 corresponding to the first pixel PX1 and the center of the light emitting pattern LA2-2 corresponding to the second pixel PX2 adjacent to the first pixel PX1. On the other hand, the shortest distance DLAD2 between the light emitting pattern LA2-1 corresponding to the first pixel PX1 and the light emitting pattern LA2-2 corresponding to the second pixel PX2 adjacent to the first pixel PX1 is shorter than the shortest distance DLAD1 between the light emitting pattern LA1-1 corresponding to the first pixel PX1 and the light emitting pattern LA1-2 corresponding to the second pixel PX2 adjacent to the first pixel PX1.

As a result, the external luminous efficiency may be improved. That is, in the display device according to an embodiment of the present disclosure, the light emitting area is expanded by the extension of the light emitting layer 172, and external luminous efficiency may be improved by totally reflecting the light emitted from the plurality of light emitting elements LEL by the light control layer 190 and the micro lens MLA.

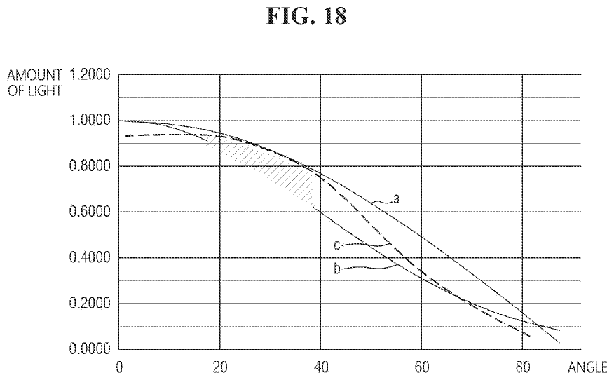

FIG. 18 is a diagram for explaining a light emission profile in a display device according to an embodiment.

In the graph of FIG. 18, the horizontal axis represents the angle of the incident light of the display device, and the vertical axis represents the amount of light according to the angle of the incident light.

In FIG. 18, a represents an ideal light emission profile, and b represents the light emission profile of a display device according to a comparative example in which the second pixel electrodes 171-2 and 171a-2 and the light emitting layer 172 are not extended to the second opening (OP2 in FIG. 6) without disposing the light control layers 190 and 290 and the micro lens MLA. Also, c arranges the light control layers 190 and 290 and the micro lens MLA according to an embodiment of the present disclosure and represents the light emission profile of the display device in which the second pixel electrodes 171-2 and 171a-2 and the light emitting layer 172 are extended to the second opening (OP2 in FIG. 6).

Referring to a, b, and c of FIG. 18, the display device in which light control layers 190 and 290 and the micro lens MLA are disposed and the second pixel electrodes 171-2 and 171a-2 and the light emitting layer 172 are extended to the second opening (OP2 in FIG. 6) according to an embodiment of the present disclosure represents results similar to the ideal light emission profile when the incident angle is about 20 degrees to about 40 degrees. Also, the display device in which light control layers 190 and 290 and the micro lens MLA are disposed and the second pixel electrodes 171-2 and 171a-2 and the light emitting layer 172 are extended to the second opening (OP2 in FIG. 6) according to an embodiment of the present disclosure represents results more similar to the ideal light emission profile compared to the display device according to a comparative example when the incident angle is about 15 degrees to about 70 degrees.

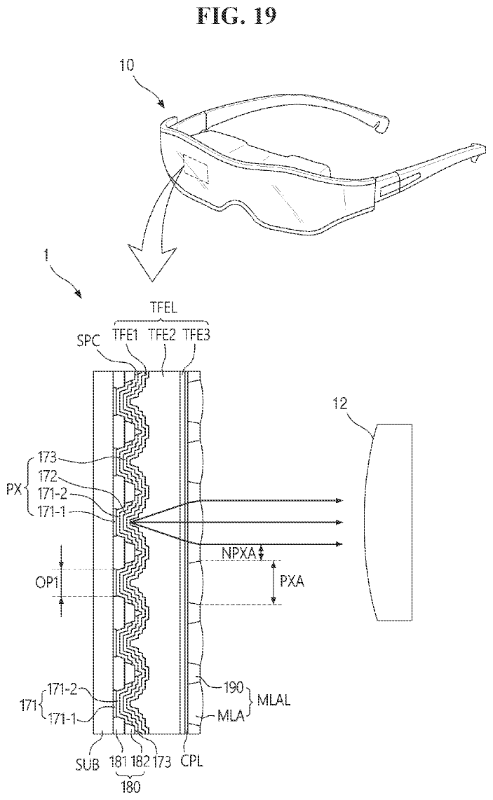

FIG. 19 is a cross-sectional view illustrating a head mounted display device including the display devices illustrated in FIGS. 4 to 7. For convenience of explanation, a further description of components and technical aspects previously described with reference to FIGS. 4 to 7 may be omitted.

Referring to FIGS. 4 and 19, a head mounted display device 10 according to an embodiment of the present disclosure may include a first display unit 1 and a lens unit 12. The head mounted display device 10 according to an embodiment of the present disclosure may further include a camera, an infrared sensor, a signal processor, and a frame mountable on a user's head.

The lens unit 12 may receive light from the first display unit 1. The lens unit 12 may be disposed between an object and a user in an embodiment. The lens unit 12 may be formed of an opaque lens, allowing for the implementation of virtual reality in an embodiment. In an embodiment, the lens unit 12 may be configured as a transparent lens or a translucent lens, allowing for the implementation of augmented reality. The lens unit 12 may be a convex lens in an embodiment.

In the first display unit 1 as shown in FIG. 4, the light control layers 190 and the micro lens MLA are disposed, and the second pixel electrodes 171-2 and the light emitting layer 172 may be extended to the second opening (OP2 in FIG. 6). The light emitting area is expanded by the extension of the light emitting layer 172 emitting light having an angle of about 69° or more incident on the capping layer CPL among the light emitted from the light emitting layer 172. As a result, external luminous efficiency may be improved by totally reflecting the light emitted from the light emitting layer 172 by the light control layer 190 and the micro lens MLA.

The user may enlarge and view the image of the first display unit 1 by the lens unit 12. However, a screen door effect may be generated by the enlarged environment. That is, the space between banks in the display unit may be visually recognized by the user due to the magnification environment. However, an area visible to the user by the magnification environment corresponds to a non-emitting area.

As described above, the head mounted display device according to an embodiment of the present disclosure may improve external light emitting efficiency and increase the area of the light emitting area. This may be expressed as a decrease in the non-emitting area.

That is, the head mounted display device according to an embodiment of the present disclosure may reduce the area of the non-emitting area and reduce the area of the non-emitting area that is visually recognized by the user due to the enlarged environment. Accordingly, the screen door effect may be improved.

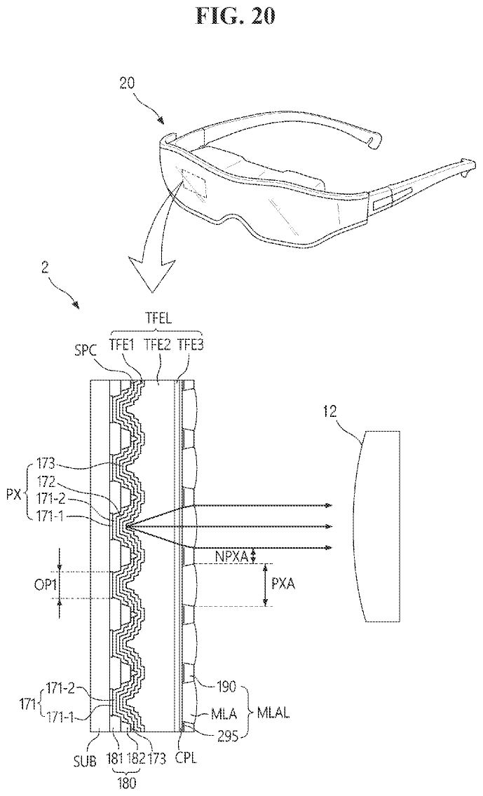

FIG. 20 is a cross-sectional view of a head mounted display device including the display devices illustrated in FIGS. 11 and 12. For convenience of explanation, a further description of components and technical aspects previously described with reference to FIGS. 11 and 12 may be omitted.

Referring to FIGS. 11 and 20, the head mounted display device 20 according to an embodiment of the present disclosure may include a second display unit 2 and the lens unit 12. The head mounted display device 20 according to an embodiment of the present disclosure may further include a camera, an infrared sensor, a signal processor, and a frame mountable on a user's head.

The lens unit 12 may receive light from the second display unit 2.

In the second display unit 2, the light control layers 190 and 290, the light blocking pattern 295, and the micro lens MLA are disposed and the second pixel electrodes 171-2 and 171a-2 and the light emitting layer 172 may be extended to the second opening (OP2 in FIG. 12) like the display device shown in one of FIGS. 6, 8, and 9.

The light emitted from the light emitting layer 172 having an angle of about 69° or more incident on the capping layer CPL is totally reflected by the light control layer 190 and the second pixel electrode 171-2. As a result, the second display unit 2 may expand the light emitting area. This means that the effective light emitting area ratio may be increased.

Accordingly, the head mounted display device according to an embodiment of the present disclosure may improve the screen door effect by increasing the effective light emitting area ratio.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a substrate;
a bank disposed on the substrate and having a multi-layered structure having an opening;
a light emitting element disposed in the opening and comprising a pixel electrode, a light emitting layer, and a common electrode;
a thin film encapsulating layer disposed on the light emitting element and the bank;
a micro lens disposed on the thin film encapsulating layer and overlapping the light emitting element; and
a light control layer disposed on the thin film encapsulating layer and surrounding the micro lens,
wherein a refractive index of the micro lens is greater than a refractive index of the light control layer,
wherein the pixel electrode is disposed in the opening and extends along an inner surface of the bank, and the light emitting layer extends along the inner surface of the bank on the pixel electrode.

2. The display device of claim 1, wherein the pixel electrode comprises a first pixel electrode and a second pixel electrode disposed on the first pixel electrode,
wherein the bank comprises a first bank comprising a first inner surface covering an end of the first pixel electrode and defining a first opening and a second bank disposed on the first bank and comprising a second inner surface defining a second opening corresponding to the first opening,
wherein a width of the second opening is wider than a width of the first opening.

3. The display device of claim 2, wherein a second internal angle between an upper surface of the substrate and the second inner surface of the second bank is greater than a first internal angle between the upper surface of the substrate and the first inner surface of the first bank.

4. The display device of claim 2, wherein the second pixel electrode comprises:
a first electrode area disposed inside the first opening;
a second electrode area extending from the first electrode area along the first inner surface of the first bank; and
a third electrode area extending from the second electrode area and covering at least a portion of an upper portion of the first bank exposed by the second opening.

5. The display device of claim 4, wherein the light emitting layer comprises:
a first light emitting layer area disposed inside the first opening on the first electrode area;
a second light emitting layer area extending along the first inner surface of the first bank on the second electrode area; and
a third light emitting layer area extending from the second light emitting layer area and disposed on the third electrode area.

6. The display device of claim 5, wherein the third light emitting layer area covers the third electrode area.

7. The display device of claim 2, wherein the second pixel electrode comprises:
a first electrode area disposed inside the first opening;
a second electrode area extending from the first electrode area along the first inner surface of the first bank;
a third electrode area extended from the second electrode area and covering an upper portion of the first bank exposed by the second opening; and
a fourth electrode area extending from the third electrode area along the second inner surface of the second bank.

8. The display device of claim 7, wherein the light emitting layer comprises:
a first light emitting layer area disposed inside the first opening on the first electrode area;
a second light emitting layer area extending from the second electrode area along the first inner surface of the first bank;
a third light emitting layer area extending from the second light emitting layer area and disposed on the third electrode area;
a fourth light emitting layer area extending along the second inner surface of the second bank from the third light emitting layer area on the fourth electrode area; and
a fifth light emitting layer area extending from the fourth light emitting layer area and covering a portion of an upper portion of the second bank.

9. The display device of claim 8, wherein the fifth light emitting layer area has a thickness that gradually decreases toward an edge.

10. The display device of claim 8, wherein the fifth light emitting layer area partially overlaps the light control layer.

11. The display device of claim 1, further comprising:
a capping layer disposed on the bank,
wherein the micro lens and the light control layer are disposed on the capping layer,
wherein the refractive index of the micro lens is less than or equal to a refractive index of the capping layer.

12. The display device of claim 1, wherein the refractive index of the micro lens differs from the refractive index of the light control layer by about 0.1 or more and about 0.2 or less.

13. The display device of claim 2, wherein a diameter of the micro lens is larger than a diameter of the second opening.

14. The display device of claim 1, wherein the micro lens has a curvature of about 0.12 or more and about 0.2 or less.

15. The display device of claim 3, wherein the light control layer has an inclination angle on a surface in contact with the micro lens,
wherein the inclination angle is greater than the second internal angle.

16. The display device of claim 2, wherein at least one of the first bank and the second bank comprises an opaque material that blocks light.

17. The display device of claim 2, wherein at least one of the first bank and the second bank is formed of a transparent organic material.

18. The display device of claim 1, further comprising:
a light blocking pattern disposed under the light control layer and covered by the light control layer.

19. A display device, comprising:
a substrate;
a bank disposed on the substrate and having a multi-layered structure having an opening;
a light emitting element disposed in the opening and comprising a pixel electrode, a light emitting layer, and a common electrode;
a thin film encapsulating layer disposed on the light emitting element and the bank;
a capping layer disposed on the thin film encapsulating layer;
a micro lens disposed on the capping layer and overlapping the light emitting element; and
a light control layer disposed on the capping layer and surrounding the micro lens,
wherein a refractive index of the micro lens is greater than a refractive index of the light control layer and less than or equal to a refractive index of the capping layer,
wherein the light emitting layer extends along an inner surface of the bank on the pixel electrode.

20. The display device of claim 19, wherein the refractive index of the micro lens differs from the refractive index of the light control layer by about 0.1 or more and about 0.2 or less.

21. The display device of claim 20, wherein the pixel electrode comprises a first pixel electrode and a second pixel electrode disposed on the first pixel electrode,
wherein the bank comprises a first bank comprising a first inner surface covering an end of the first pixel electrode and defining a first opening and a second bank disposed on the first bank and comprising a second inner surface defining a second opening corresponding to the first opening,
wherein a width of the second opening is wider than a width of the first opening.

22. The display device of claim 21, wherein a second internal angle between an upper surface of the substrate and the second inner surface of the second bank is greater than a first internal angle between the upper surface of the substrate and the first inner surface of the first bank.

23. The display device of claim 19, wherein the light emitting layer partially overlaps the light control layer.
